(19) United States
(12) Patent Application Publication
(10) Pub. No.: US 2018/0350708 A1
(43) Pub. Date: Dec. 6, 2018

(54) PACKAGE STRUCTURE AND MANUFACTURING METHOD THEREOF

(71) Applicant: Powertech Technology Inc., Hsinchu County (TW)

(72) Inventors: Shang-Yu Chang Chien, Hsinchu County (TW); Hung-Hsin Hsu, Hsinchu County (TW); Nan-Chun Lin, Hsinchu County (TW)

(73) Assignee: Powertech Technology Inc., Hsinchu County (TW)

(21) Appl. No.: 15/614,617

(22) Filed: Jun. 6, 2017

(51) Int. Cl. H01L 23/31; H01L 21/56; H01L 23/48; H01L 23/538; H01L 21/768

(52) U.S. Cl. CPC H01L 23/3128; H01L 21/56; H01L 21/76885; H01L 23/48; H01L 23/538; H01L 23/3114

(57) ABSTRACT

A package structure includes a redistribution structure, a die, an insulation encapsulation, a protection layer, and a plurality of conductive terminals. The redistribution structure has a first surface and a second surface opposite to the first surface. The die is electrically connected to the redistribution structure. The die has an active surface, a rear surface opposite to the active surface, and lateral sides between the active surface and the rear surface. The insulation encapsulation encapsulates lateral sides of the die and the first surface of the redistribution structure. The protection layer is disposed on the rear surface of the die and the insulation encapsulation. The conductive terminals are formed on the second surface of the redistribution structure.

### BACKGROUND OF THE INVENTION

### 1. Field of the Invention

The present invention generally relates to a package structure, in particular, to a package structure having a protection layer.

### 2. Description of Related Art

Semiconductor package technology has been progressed in recent years in order to develop products with smaller volume, lighter weight, higher integration level and lower manufacturing cost. Meanwhile, miniaturizing the package structure while maintaining the reliability of the package has become a challenge to researchers in the field.

### SUMMARY OF THE INVENTION

Accordingly, the present invention provides a semiconductor package structure and a manufacturing method thereof, which effectively enhances the reliability of the package structure at lower manufacturing cost.

The present invention provides a package structure including a redistribution structure, a die, an insulation encapsulation, a protection layer, and a plurality of conductive terminals. The redistribution structure has a first surface and a second surface opposite to the first surface. The die is electrically connected to the redistribution structure. The die has an active surface, a rear surface opposite to the active surface, and lateral sides between the active surface and the rear surface. The insulation encapsulation encapsulates the lateral sides of the die and the first surface of the redistribution structure. The protection layer is disposed on the rear surface of the die and the insulation encapsulation. The conductive terminals are formed on the second surface of the redistribution structure.

The present invention provides a manufacturing method of a package structure. The method includes at least the following steps. A carrier substrate is provided. A protection layer is formed over the carrier substrate. A plurality of dies are disposed over the protection layer. Each die has an active surface, a rear surface opposite to the active surface, and lateral sides between the active surface and the rear surface. The rear surfaces of the dies are adhered to the protection layer. The lateral sides of the dies are encapsulated using an insulation encapsulation. A redistribution structure is formed over the dies and the insulation encapsulation. The redistribution structure is electrically connected to the dies. The carrier substrate is separated from the protection layer. A plurality of conductive terminals are formed on the redistribution structure.

Based on the above, the protection layer is formed over the die and the insulation encapsulation. The die and the insulation encapsulation are well protected by the protection layer such that the issue of moisture penetration through the interface between the insulation encapsulation and the die may be effectively eliminated. In addition, since a coefficient of thermal expansion (CTE) of the carrier substrate is closer to a CTE of the protection layer as compared to a CTE of the insulation encapsulation, the warpage issues during manufacturing process of the package structure may be sufficiently alleviated. Therefore, the reliability of the package structure may be ensured. Moreover, by adapting B-stage material as the protection layer, the overall strength of the package structure may be enhanced. In addition, the issues of delamination and die shift during manufacturing process of the package structure may also be eliminated. Furthermore, by using the protection layer to replace the over-molding portion of the insulation encapsulation, the manufacturing cost of the package structure may be effectively reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 A to FIG. 1I are schematic cross-sectional views illustrating a manufacturing method of package structures according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

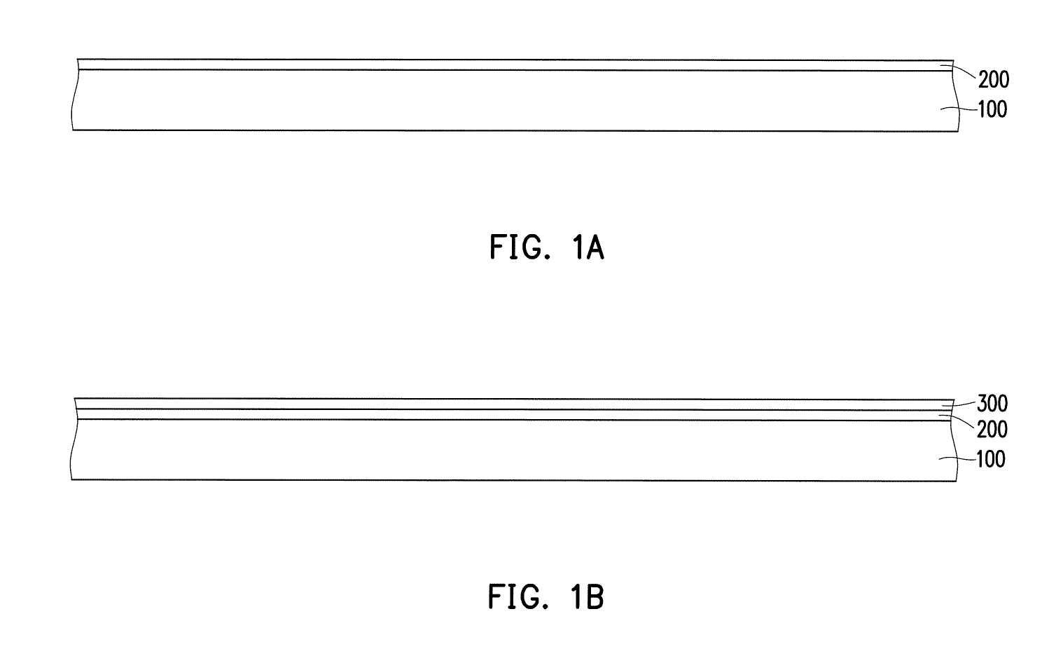

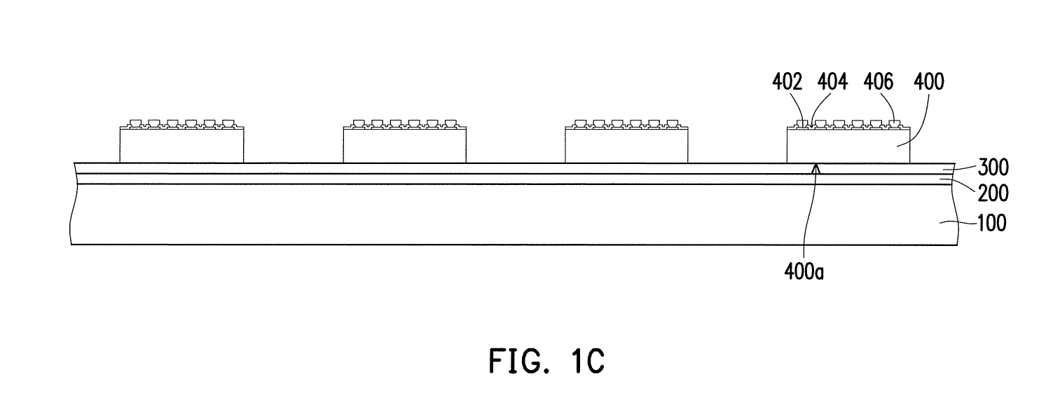

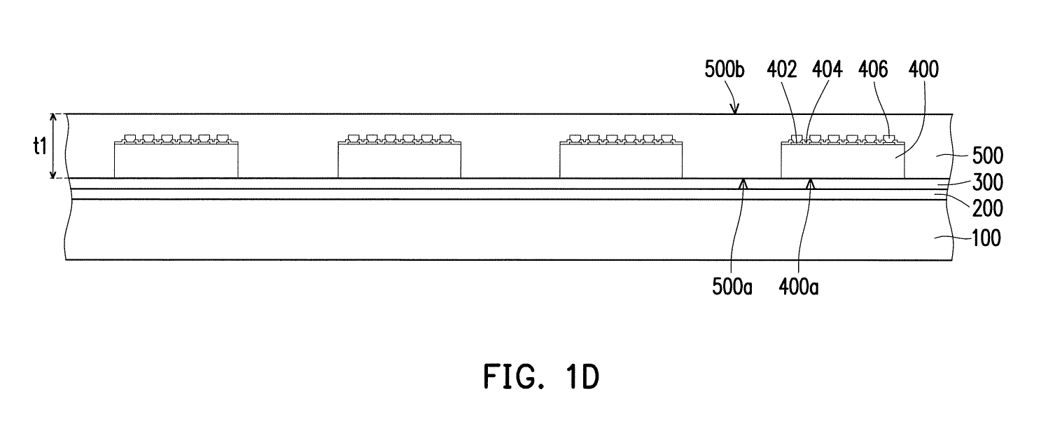

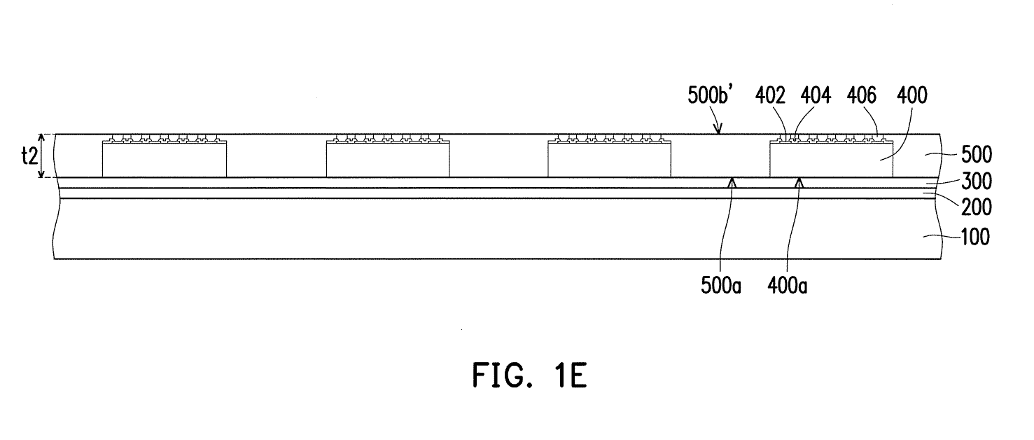

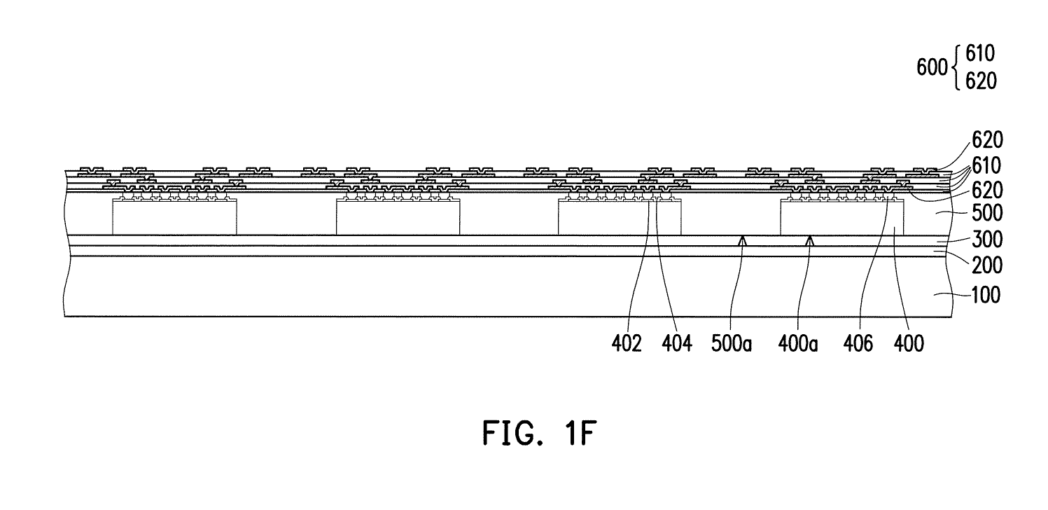

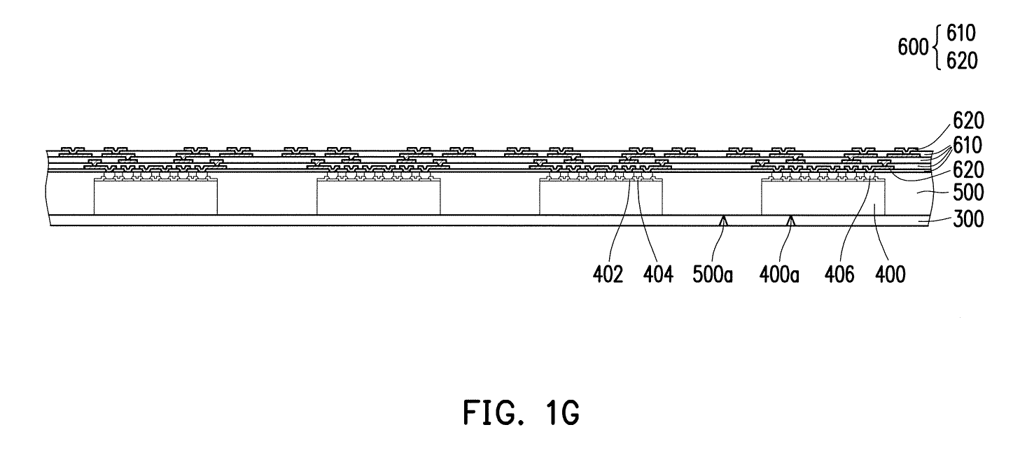

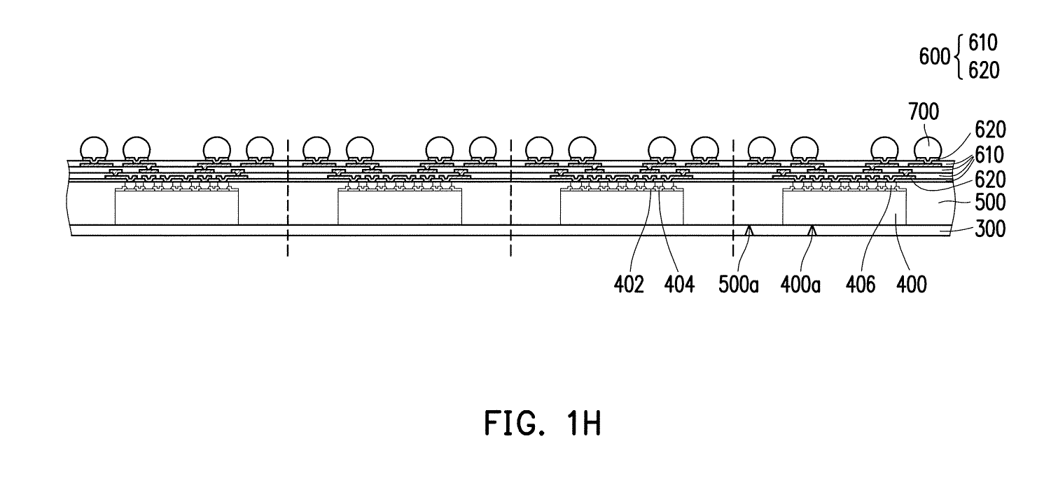

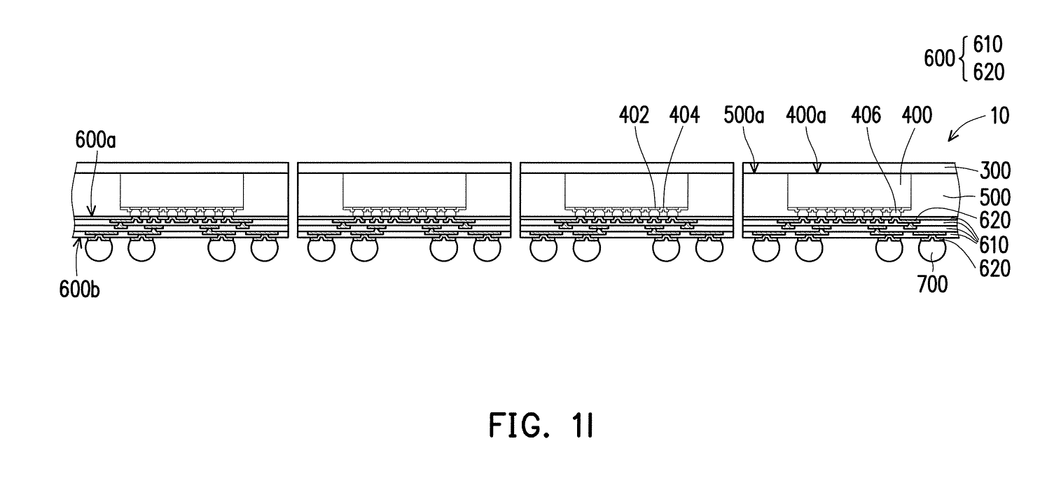

FIG. 1 A to FIG. 11 are schematic cross-sectional views illustrating a manufacturing method of package structures 10 according to an embodiment of the present invention.

Referring to FIG. 1A, a carrier substrate 100 is provided. The carrier substrate 100 may be made of glass, silicon, plastic, or other suitable materials. A release layer 200 is formed over the carrier substrate 100 to temporarily enhance the adhesion between the carrier substrate 100 and the elements subsequently formed thereon. The release layer 200 may be a LTHC (light to heat conversion) adhesive layer or other suitable adhesive layers.

Referring to FIG. 1B, a protection layer 300 is formed over the release layer 200. The release layer 200 may be disposed between the protection layer 300 and the carrier substrate 100. The protection layer 300 may be made of B-stage materials. For example, the protection layer 300 may include resins constituting a die attach film (DAF). The protection layer 300 may be formed by a coating process or a lamination process. For example, the protection layer 300 may be a dry film and may be adhered to the release layer 200 through the lamination process. Alternatively, a solution of the protection layer 300 (liquid type) may be coated onto the release layer 200 through the coating process. Subsequently, the solution is dried or cured to form a solid layer of the protection layer 300. In some embodiments, a thickness of the protection layer 300 ranges between 10 μm and 40 μm. Within this thickness range, the protection layer 300 may sufficiently protect other elements in the package structure 10 while maintaining the thin feature of the package structure 10.

Referring to FIG. 1C, a plurality of dies 400 are disposed over the protection layer 300. The protection layer 300 may be a DAF used to adhere the dies 400 to the protection layer 300. The protection layer 300 may further serve as a buffer layer to avoid delamination between other components and the carrier substrate 100 during the manufacturing process of the package structure 10.

Each of the dies 400 has a plurality of conductive connectors 406 formed thereon. The dies 400 may be manufactured by the following steps. First, a wafer (not illustrated) having a plurality of pads 402 formed thereon is provided. Subsequently, a passivation layer (not illustrated) is formed to cover the pads 402 and the wafer. The passivation layer is patterned to render a plurality of passivation patterns 404. The passivation layer may be patterned through a photolithography and an etching process, for example. The passivation patterns 404 expose at least part of the pads 402. Thereafter, the conductive connectors 406 are formed over the pads 402. The conductive connectors 406 may be formed through a plating process. The plating process is, for example, electro-plating, electroless-plating, immersion plating, or the like. Afterward, the wafer is grinded from a rear surface opposite to the conductive connectors 406 and is diced to obtain a plurality of dies 400.

A surface of each die 400 having the conductive connectors 406 formed thereon is considered as an active surface of the die 400. On the other hand, the surface 400a opposite to the active surface is considered as a rear surface of the die 400. Each die 400 also includes lateral sides between the active surface and the rear surface (surface 400a). As illustrated in FIG. I C, the active surface of each die 400 faces away from the protection layer 300. The rear surface (surface 400a) of each die 400 may be physically attached to the protection layer 300. In some embodiments, the conductive connectors 406 may be conductive bumps, conductive pillars, or a combination thereof. A material of the conductive connectors 406 may be copper, aluminium, tin, gold, silver, or a combination thereof.

Referring to FIG. 1D, an insulation encapsulation 500 is used to encapsulate the dies 400. The insulation encapsulation 500 may be disposed over the protection layer 300 and the dies 400 such that the insulation encapsulation 500 completely covers the dies 400. For example, the insulation encapsulation 500 encapsulates the lateral sides of the dies 400. In some embodiments, the insulation encapsulation 500 may include molding compounds formed by a molding process. In some alternative embodiments, the insulation encapsulation 500 may be formed by an insulating material such as epoxy or other suitable resins. As illustrated in FIG. 1D, the insulation encapsulation 500 has a first surface 500a and a second surface 500b opposite to the first surface 500a. The first surface 500a of the insulation encapsulation 500 is directly/physically in contact/adhered to the protection layer 300. As mentioned above, the rear surface (surface 400a) of each die 400 is also physically attached to the protection layer 300. Therefore, the first surface 500a of the insulation encapsulation 500 is coplanar with the surface 400a of each die 400. On the other hand, the second surface 500b may have a level height higher than a top surface of the dies 400. In other words, a thickness t1 of the insulation encapsulation 500 is larger than a thickness of the dies 400.

In some embodiments, a coefficient of thermal expansion (CTE) of the carrier substrate 100 is closer to a CTE of the protection layer 300 as compared to a CTE of the insulation encapsulation 500. For example, the CTE of the carrier substrate 100 may range between 3 and 20, the CTE of the protection layer 300 may range between 5 and 40, and the CTE of the insulation encapsulation 500 may range between 10 and 70. On the other hand, a Young's modulus of the protection layer 300 is less than a Young's modulus of the insulation encapsulation 500. For example, the Young's modulus of the protection layer 300 may range between 0.5 GPa and 5 GPa and the Young's modulus of the insulation encapsulation 500 may range between 5 GPa and 20 GPa. Due to the foregoing property, with the aid of the protection layer 300, the issue of warpage in the package structure 10 originated from the manufacturing processes thereof may be eliminated and the overall strength of the package structure 10 may be enhanced. Moreover, a moisture absorption rate of the protection layer 300 is lower than a moisture absorption rate of the insulation encapsulation 500. Therefore, the die 400 and the insulation encapsulation 500 are well protected by the protection layer 300 such that the issue of moisture penetration through the interface between the insulation encapsulation 500 and the die 400 may be effectively eliminated.

As mentioned above, the protection layer 300 may also serve as a DAF. The dies 400 are fixed onto the protection layer 300. During the formation process of the insulation encapsulation 500 (for example, the molding process), the issue of die shift may be alleviated. Therefore, the overall yield of the package structure 10 may be sufficiently increased.

Referring to FIG. 1E, the insulation encapsulation 500 is thinned to a thickness t2 to expose part of each die 400. As illustrated in FIG. 1E, the thinned second surface 500b′ of the insulation encapsulation 500 exposes top surfaces of the conductive connectors 406. In some embodiments, the insulation encapsulation 500 is thinned to expose top surfaces of the conductive connectors 406. An etching process may be further performed on the conductive connectors 406. For example, the conductive connectors 406 may be partially removed such that top surfaces of the conductive connectors 406 are slightly lower than the thinned second surface 500b′ of the insulation encapsulation 500. In some embodiments, the top surfaces of the conductive connectors 406 are 1 μm to 3 μm lower than the thinned second surface 500b′ of the insulation encapsulation 500. As a result, a surface roughness of the insulation encapsulation 500 and the conductive connectors 406 may be enhanced, thereby increasing an adhesive property with layers subsequently formed thereon. The thinning process may be achieved by, for example, mechanical grinding, Chemical-Mechanical Polishing (CMP), etching, or other suitable methods. The etching process for the conductive connectors 406 may include anisotropic etching or isotropic etching.

Referring to FIG. 1F, a redistribution structure 600 is formed over the dies 400 and the insulation encapsulation 500. The redistribution structure 600 is electrically connected to the conductive connectors 406 of the dies 400. The redistribution structure 600 may include at least one dielectric layer 610 and a plurality of conductive elements 620 embedded in the dielectric layer 610. As illustrated in FIG. 1F, the redistribution structure 600 includes four dielectric layers 610. However, the number of the dielectric layer 610 is not limited and may be adjusted based on circuit design. The conductive elements 620 may include a plurality of trace layers and a plurality of interconnect structures connecting the trace layers. The first trace layer may be directly in contact with the conductive connectors 406 to render electrical connection between the dies 400 and the redistribution structure 600. The second dielectric layer 610 (counted from bottom to top) exposes part of the first trace layer (bottommost trace layer illustrated in FIG. 1F) such that the first trace layer may be electrically connected to other trace layers through the interconnect structures. The last trace layer (the topmost conductive element 620 illustrated in FIG. 1F) is electrically connected to at least part of the third trace layer exposed by the last dielectric layer 610. The last trace layer may be used for electrical connection with elements formed in the subsequent processes. In some embodiments, the last trace layer is referred to as under-bump metallization (UBM). The conductive elements 620 may be formed by a plating process and may include copper, aluminium, gold, silver, tin, or a combination thereof.

Referring to FIG. 1G, the carrier substrate 100 is separated from the protection layer 300 by a debonding process. For example, the separation is performed at an interface between the release layer 200 and the protection layer 300. In some embodiments, thermal energy or optical energy (such as heating or UV irradiation) may be applied to the release layer 200. Upon stimulation, the release layer 200 loses adhesive property and may be readily peeled off from the protection layer 300.

Referring to FIG. 1H, a plurality of conductive terminals 700 are disposed on the redistribution structure 600. In some embodiments, the conductive terminals 700 are disposed over the conductive element 620 (last trace layer; UBM). The conductive terminals 700 may be formed by, for example, a ball placement process and a reflow process. Thereafter, a singulation process is performed to singulate the dies 400. The insulation encapsulation 500 is sawed between adjacent dies 400 to obtain a plurality of package structures 10, as illustrated in FIG. 1I. The singulation process includes, for example, cutting with rotating blade or laser beam.

Referring to FIG. 1I, each package structure 10 includes a redistribution structure 600, a die 400, an insulation encapsulation 500, a protection layer 300, and a plurality of conductive terminals 700. The redistribution structure 600 has a first surface 600a and a second surface 600b opposite to the first surface 600a. The die 400 is over the first surface 600a of the redistribution structure 600 and is electrically connected to the redistribution structure 600. In some embodiments, the die 400 is electrically connected to the redistribution structure 600 though flip-chip bonding. Each die 400 has an active surface, a rear surface (surface 400a) opposite to the active surface, and lateral sides between the active surface and the rear surface. The insulation encapsulation 500 is over the first surface 600a of the redistribution structure 600 and encapsulates the lateral sides of the die 400 and the first surface 600a of the redistribution structure 600. A first surface 500a of the insulation encapsulation 500 is coplanar with a rear surface (surface 400a) of the die 400. The protection layer 300 is disposed on the rear surface (surface 400a) of the die 400 and the insulation encapsulation 500. A portion of the protection layer 300 covers the die 400 and another portion of the protection layer 300 covers the insulation encapsulation 500. In other words, the interface between the die 400 and the insulation encapsulation 500 is sealed by the protection layer 300 to prevent moisture penetration. In some embodiments, the protection layer 300 may have a color of black. As such, the laser marking/engraving of date codes on the protection layer 300 may be seen clearly. Moreover, since the cost for the protection layer 300 is lower than the cost of the insulation encapsulation 500, the overall manufacturing cost of the package structure 10 may be reduced. As illustrated in

FIG. 1I, the conductive terminals 700 are over the second surface 600b of the redistribution structure 600.

In light of the foregoing, the protection layer is formed over the die and the insulation encapsulation. The die and the insulation encapsulation are well protected by the protection layer such that the issue of moisture penetration through the interface between the insulation encapsulation and the die may be effectively eliminated. In addition, since a coefficient of thermal expansion (CTE) of the carrier substrate is closer to a CTE of the protection layer as compared to a CTE of the insulation encapsulation, the warpage issues during manufacturing process of the package structure may be sufficiently alleviated. Therefore, the reliability of the package structure may be ensured. Moreover, by adapting B-stage material as the protection layer, the overall strength of the package structure may be enhanced. In addition, the issues of delamination and die shift during manufacturing process of the package structure may be eliminated. Furthermore, by using the protection layer to replace the over-molding portion of the insulation encapsulation, the manufacturing cost of the package structure may be effectively reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A package structure, comprising:
a redistribution structure having a first surface and a second surface opposite to the first surface;
a die electrically connected to the redistribution structure, the die having an active surface, a rear surface opposite to the active surface, and lateral sides between the active surface and the rear surface;
an insulation encapsulation encapsulating the lateral sides of the die and the first surface of the redistribution structure;
a protection layer disposed on the rear surface of the die and the insulation encapsulation, wherein a Young's modulus of the protection layer is less than a Young's modulus of the insulation encapsulation, and the protection layer has laser marking or engraving;
and a plurality of conductive terminals formed on the second surface of the redistribution structure.

2. The package structure according to claim 1, wherein the protection layer comprises a B-stage material.

3. (canceled)

4. The package structure according to claim 1, wherein a Young's modulus of the protection layer ranges between 0.5 GPa and 5 GPa.

5. The package structure according to claim 1, wherein a moisture absorption rate of the protection layer is lower than a moisture absorption rate of the insulation encapsulation.

6. The package structure according to claim 1, wherein a color of the protection layer is black.

7. The package structure according to claim 1, wherein a thickness of the protection layer ranges between 10 μm and 40 μm.

8. The package structure according to claim 1, wherein the redistribution structure comprises at least one dielectric layer and a plurality of conductive elements embedded in the dielectric layer, and the die is electrically connected to the conductive elements.

9. The package structure according to claim 1, wherein the die is electrically connected to the redistribution structure through flip-chip bonding.

10. The package structure according to claim 1, wherein the rear surface of the die is coplanar with a surface of the insulation encapsulation.

11. A manufacturing method of a package structure, comprising:
providing a carrier substrate;
forming a protection layer over the carrier substrate, wherein the protection layer has laser marking or engraving;
disposing a plurality of dies over the protection layer, wherein each die has an active surface, a rear surface opposite to the active surface, and lateral sides between the active surface and the rear surface, and the rear surfaces of the dies are adhered to the protection layer;
encapsulating the lateral sides of the dies using an insulation encapsulation;
forming a redistribution structure over the dies and the insulation encapsulation, wherein the redistribution structure is electrically connected to the dies;
separating the carrier substrate from the protection layer, wherein the protection layer remains on the insulation encapsulation and the rear surface of the die; and
forming a plurality of conductive terminals on the redistribution structure.

12. The method according to claim 11, further comprising forming a release layer between the carrier substrate and the protection layer.

13. The method according to claim 11, wherein the protection layer is formed by a coating process or a lamination process.

14. The method according to claim 11, further comprising performing a singulation process to singulate the plurality of dies.

15. The method according to claim 11, wherein the step of encapsulating the lateral sides of the dies comprises:
disposing the insulation encapsulation over the dies such that the insulation encapsulation completely covers the dies; and
reducing a thickness of the insulation encapsulation to expose part of the die.

16. The method according to claim 11, wherein the conductive terminals are formed through a ball placement process.

17. The method according to claim 11, wherein a coefficient of thermal expansion (CTE) of the carrier substrate is closer to a CTE of the protection layer as compared to a CTE of the insulation encapsulation.

18. The method according to claim 11, wherein the protection layer comprises a B-stage material.

19. The method according to claim 11, wherein a Young's modulus of the protection layer is less than a Young's modulus of the insulation encapsulation.

20. The package structure according to claim 1, wherein a moisture absorption rate of the protection layer is less than a moisture absorption rate of the insulation encapsulation.
